(19) United States
(12) Patent Application Publication
(10) Pub. No.: US 2023/0376737 A1
(43) Pub. Date: Nov. 23, 2023

(54) 3-DIMENSIONAL ELECTRICAL ELEMENT, MACHINE LEARNING SYSTEM COMPRISING SAME, AND METHODS FOR MANUFACTURING SAID ELEMENT AND SAID SYSTEM

(71) Applicant: Kyushu Institute of Technology, Kitakyushu-shi, Fukuoka (JP)

(72) Inventors: Hirofumi Tanaka, Kitakyushu-shi, Fukuoka (JP); Yuki Usami, Kitakyushu-shi, Fukuoka (JP); Azhari Saman, Kitakyushu-shi, Fukuoka (JP)

(73) Assignee: Kyushu Institute of Technology, Kitakyushu-shi, Fukuoka (JP)

(21) Appl. No.: 18/031,290

(22) PCT Filed: Oct. 7, 2021
(86) PCT No.: PCT/JP2021/037158

§ 371 Date: Apr. 11, 2023

(30) Foreign Application Priority Data
Oct. 16, 2020 (JP) 2020-174660

(51) Int. Cl. G06N 3/063; H10K 19/00

(52) U.S. Cl. CPC G06N 3/063; H10K 19/201

(57) ABSTRACT

A three-dimensional electric element 10 comprises four or more nonlinear units 11 each having nonlinear current-voltage characteristics and an electric conductor 12 connecting the nonlinear units 11, and the nonlinear units 11 are arranged in a three-dimensional manner. A machine learning system 20 comprises a three-dimensional electric element 10 that includes four or more nonlinear units 11 each having nonlinear current-voltage characteristics and an electric conductor 12 connecting the nonlinear units 11 being arranged in a three-dimensional manner, and an input electrode 13 and an output electrode 14, the input electrode 13 and the output electrode 14 are connected to the three-dimensional electric element 10.

### TECHNICAL FIELD

The present invention relates to a 3D electrical element that functions as a neuron element that mimics a neuron (nerve cell), a machine learning system thereof, and a manufacturing method for each.

### BACKGROUND ART

Various studies have been conducted to build neural network systems. Examples of the method for constructing a neural network system include designing a neuron element with an electronic circuit and having a functional molecular element function as a neuron element (see Patent Document 1). By using functional molecular elements, it is possible to make the neural network system more compact than electronic circuiting.

### CITATION LIST

### Patent Literature

Patent Document 1: Japanese Unexamined Patent Application Publication No. 2009-157600

### SUMMARY OF INVENTION

### Technical Problem

However, there was a limit to the compactness of neural network systems employing conventional functional molecular elements. In addition, the compactness of the system is not a problem that manifests itself only in neural networks, but also a problem that is common to machine learning systems in general.

An object of the present invention is made in view of such circumstances, and an object of the present invention is to provide a three-dimensional electric element capable of compacting the machine learning system, a machine learning system having the same, and a manufacturing method for each.

### Solution to Problem

In order to achieve the above object, according to a first aspect of the present invention, there is provided a three-dimensional electric element, comprising:
four or more nonlinear units each having nonlinear current-voltage characteristics; and
an electric conductor connecting the nonlinear units, the nonlinear units being arranged in a three-dimensional manner.

In order to achieve the above object, according to a second aspect of the present invention, there is provided a machine learning system, comprising:
a three-dimensional electric element, the three-dimensional electric element including four or more nonlinear units each having nonlinear current-voltage characteristics and an electric conductor connecting the nonlinear units, the nonlinear units being arranged in a three-dimensional manner; and
   an input electrode and an output electrode, each of the input electrode and the output electrode being connected to the three-dimensional electric element.

In order to achieve the above object, according to a third aspect of the present invention, there is provided a method for manufacturing a three-dimensional electric element, comprising:
a step of causing a dispersion liquid to be immersed in a porous structure to obtain a dispersion liquid-containing body, the dispersion liquid in which four or more nonlinear units each having nonlinear current-voltage characteristics and an electric conductor connecting the nonlinear units are put; and
a step of causing the dispersion liquid-containing body to be cured with a curable resin to obtain a three-dimensional electric element, the three-dimensional electric element including the nonlinear units arranged in a three-dimensional manner.

In order to achieve the above object, according to a fourth aspect of the present invention, there is provided a method for manufacturing a machine learning system, comprising:
a step of causing a dispersion liquid to be immersed in a porous structure to obtain a dispersion liquid-containing body, the dispersion liquid in which four or more nonlinear units each having nonlinear current-voltage characteristics and an electric conductor connecting the nonlinear units are put;
a step of causing the dispersion liquid-containing body to be cured with a curable resin to obtain a three-dimensional electric element, the three-dimensional electric element including the nonlinear units arranged in a three-dimensional manner; and
a step of connecting an input electrode and an output electrode to the three-dimensional electric element.

The three-dimensional electric element according to the first invention and the machine learning system according to the second invention each include four or more nonlinear units exhibiting nonlinear current-voltage characteristics and an electrical conductor connecting each nonlinear unit. In addition, the nonlinear unit is arranged in a three-dimensional shape (three-dimensional structure). Therefore, it is possible to achieve compactness compared to conventional machine learning systems in which nonlinear units are arranged in a planar shape (two-dimensional structure). Further, the method for manufacturing the three-dimensional electric element according to the third invention and the method for manufacturing the machine learning system according to the fourth invention each manufacture the three-dimensional electric element and the machine learning system.

### BRIEF DESCRIPTION OF DRAWINGS

FIG. 1 is an explanatory drawing of a three-dimensional (Hereafter abbreviated as 3D) electrical element and a neural network system having the same which concerns on one embodiment of this invention.

FIGS. 2 (A) and (B) are explanatory diagrams of the 3D electrical element and neural network system according to the modification.

FIG. 3 is an explanatory drawing which shows the first example of the manufacturing method of the 3D electric element.

FIGS. 4 (A) and (B) are explanatory diagrams showing a state of connecting the input electrode to a 3D electrical element.

FIG. 5 is an explanatory drawing which shows the second example of the manufacturing method of the 3D electric element.

FIG. 6 is an explanatory drawing which shows a third example of the manufacturing method of a 3D electrical element.

FIG. 7 is an explanatory drawing which shows a fourth example of the manufacturing method of a 3D electric element.

FIG. 8 is an explanatory drawing which shows a fifth example of the manufacturing method of a 3D electric element.

FIG. 9 is a graph which shows the experimental result of the experimental example of waveform generation learning.

FIGS. 10 (A) and (B) are graphs showing the experimental results of the experimental example of waveform generation learning and the experimental result of the comparative example of waveform generation learning, respectively.

### DESCRIPTION OF EMBODIMENTS

Subsequently, with reference to the accompanying drawings, examples embodying the present invention will be described and provided for the understanding of the present invention.

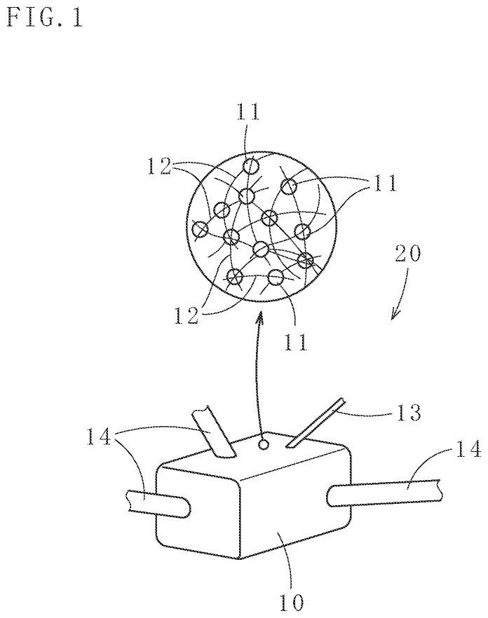

As shown in FIG. 1, the three-dimensional electrical element 10 (hereinafter abbreviated as 3D electrical element 10) according to one embodiment of the present invention includes four or more nonlinear units 11 that each exhibit nonlinear current-voltage characteristics, and a conductor 12 that electrically connects each nonlinear unit 11.

In this embodiment, the nonlinear unit 11 is particulate or a void that allows tunnel bonding, and can be formed by molecules having conductivity, ions, complexes, polymers, metals, organic materials, inorganic materials, organic-inorganic hybrid materials and mixtures thereof. For example, it is possible to employ particles of polyoxometallates as the nonlinear unit 11.

The nonlinear current-voltage characteristics shown by the nonlinear unit 11 mean that a relationship between the voltage value applied to the nonlinear unit 11 (the current value to be energized) and the voltage value (current value) output from the nonlinear unit 11 becomes nonlinear. Nonlinear current-voltage characteristics include rectification by pn junction of semiconductors, rectification by Schottky junction, electrical characteristics of tunnel junctions and coulomb blockades, and resistance changes to the applied voltage of the memory star element.

The conductor 12 may be a conductive material connecting each nonlinear unit 11. For example, organic nanowires such as carbon nanotubes, Ag, Au, Ni, Cu, Pd, Pt, Rh, Ir, Ru, Os, Fe, Co, Sn metal nanowires composed of one or more elements selected from the group consisting of Sn, and oxide nanowires composed of one or more types of oxides selected from the group consisting of IrO₂, In₂O₃, SnO₂, ITO, A composite wire made of polymerizable polymer wire, DNA, or the like on which the surface of the insulating nanowires is covered with a conductive material can be adopted as the conductor 12.

The connection of each nonlinear unit 11 by the conductor 12 may be a connection method that allows an electrical signal output from one nonlinear unit 11 to be transmitted to the other nonlinear unit 11, and each nonlinear unit 11 can be physically connected, electrically, magnetically, optically or chemically, or two or more types of these can be connected together.

Here, one 3D electrical element 10 has N nonlinear units 11 with 4 or more integers as N, and these N nonlinear units 11 are arranged in a three-dimensional manner via the conductor 12.

Here, the fact that N nonlinear units 11 are arranged in a three-dimensional manner means that at least one nonlinear unit 11 that does not touch the virtual plane in which the geometric centers of the three nonlinear units 11 arbitrarily selected from among the N nonlinear units 11 are arranged is at least one in the N nonlinear units 11. Therefore, N is 4 or more.

From the viewpoint that the 3D electrical element 10 functions stably as a neuron element, it is preferable that N is 30 or more, more preferably 100 or more, and more preferably a number as large as possible of 1000 or more.

By arranging N nonlinear units 11 in a three-dimensional shape, the 3D electrical element 10 can be made more compact than when N nonlinear units 11 are arranged in a planar shape. From the viewpoint of compacting the 3D electrical element 10, the proportion of the nonlinear unit 11 that is not located on the virtual plane among the N nonlinear units 11 is 95% or more, 90% or more, 80% or more, 70% or more, 60% or more, 50% or more, in order of preference.

In the present embodiment, a neural network system 20 which is an example of a machine learning system is configured having an input electrode 13 and an output electrode 14 connected to the 3D electrical element 10 and the 3D electrical element 10, respectively. In this embodiment, the input electrode 13 and the output electrode 14 are each in a linear shape and are formed of a conductive substance (for example, copper) as a material.

The input electrode 13 is an electrode that inputs an electrical signal to the 3D electrical element 10, and the output electrode 14 is an electrode for which an electrical signal is output from the 3D electrical element 10. Note that the position of the input electrode 13 and the output electrode 14 with respect to the 3D electrical element 10 is arbitrary, and is not limited to the position shown in FIG. 1.

When an electrical signal (e.g., a pulse signal) is input from the input electrode 13 to the 3D electrical element 10, the 3D electrical element 10 functions as a neuron element in the neural network. As a result, an electrical signal is output from the 3D electrical element 10 to the output electrode 14.

In the present embodiment, the neural network system 20 is provided with one input electrode 13 and three (that is, a plurality) of output electrodes 14, but the input electrode 13 and the output electrode 14 may each have at least one electrode.

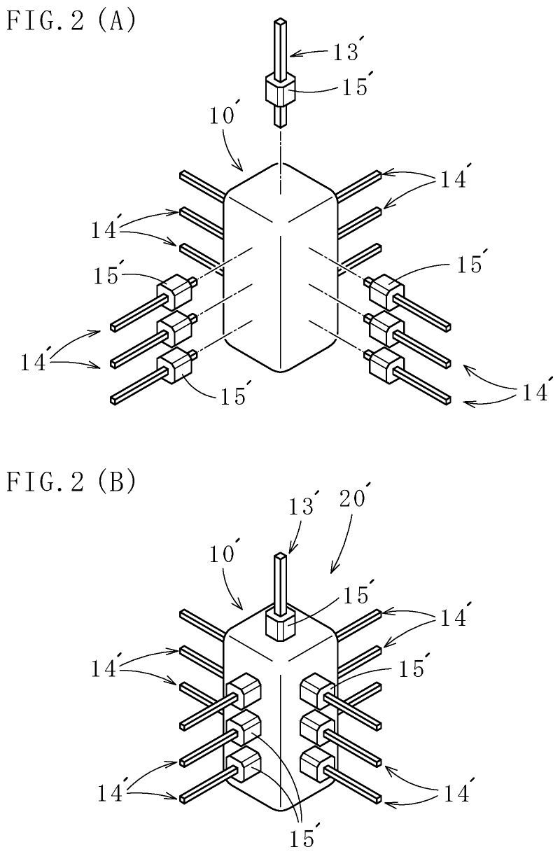

For example, as shown in FIGS. 2A and 2B, one input electrode 13′ may be is inserted from the top surface to the cube-shaped 3D electrical element 10′, and three output electrodes 14′ may be inserted from each of the four sides (the surfaces perpendicular to the inserted surface where electrode 13′ is inserted) to configure a neural network 20′. The input electrode 13′ and the output electrode 14′ have a rectangular cross-section, and the region inserted into the 3D electrical element 10′ on the longitudinal side one side and the longitudinal direction The 3D electrical element 10′ protrudes from the other side.

A plurality of input electrodes 13 can also be provided.

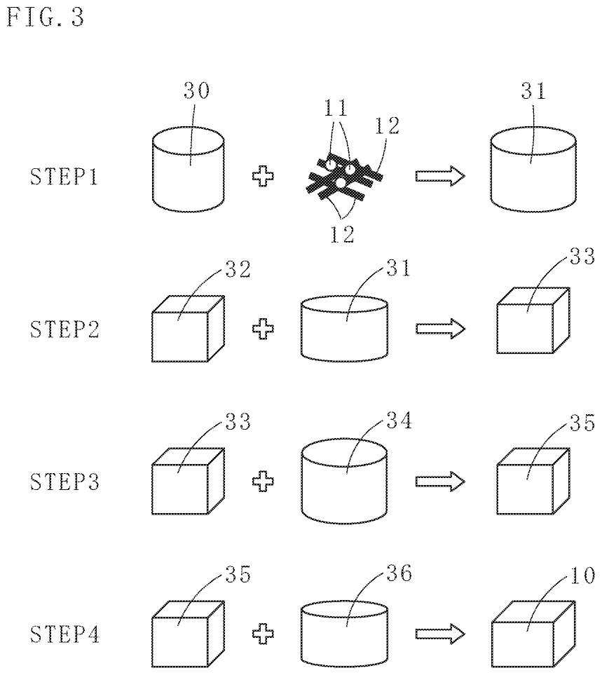

Next, with reference to FIG. 3, a manufacturing method for the 3D electrical element 10 will be described. Here, an example in which polyoxometalate particles are employed in the nonlinear unit 11 and carbon nanotubes are employed as the conductor 12.

First, as shown in FIG. 3, a large number of nonlinear units 11 (particles of polyoxomethalates) and a large number of conductors 12 (carbon nanotubes) are put in the isopropyl alcohol 30 to obtain a dispersion liquid 31 (Step 1).

The dispersion liquid 31 obtained in Step 1 is immersed in a water-soluble porous structure 32 which is an example of a porous structure such as a sugar cube, and the nonlinear unit 11 and the conductor 12 are arranged three-dimensionally to form a dispersion liquid-containing body 33 (Step 2), and the dispersion liquid-containing body 33 is immersed with polydimethylsiloxane 34, which is an example of a curable resin, and heated to cure to obtain a cured product 35 (Step 3). Then, by immersing the cured product 35 in hot water 36 at about 50-70° C. and removing the water-soluble porous structure 32 from the cured product 35, a 3D electrical element 10 in which the nonlinear unit 11 is arranged in a three-dimensional shape can be obtained (Step 4). The cured polydimethylsiloxane 34 is elastic, and the 3D electrical element 10 is sponge-shaped. Further, a machine learning system can be obtained by adding a step of connecting the input electrode 13 and the output electrode 14 to the 3D electrical element 10 obtained in Step 4. The cured polydimethylsiloxane 34 is elastic, and the 3D electrical element 10 is sponge-shaped. Further, a machine learning system can be obtained by adding a step of connecting the input electrode 13 and the output electrode 14 to the 3D electrical element 10 obtained in Step 4.

A sheet in which the nonlinear unit 11 and the conductive unit 12 are dispersed and arranged may be formed, and the sheets may be superimposed to obtain a 3D electrical element.

Further, in Step 4, the created one is used as an electric element unit, and by joining a plurality of the electric element units, it is processed into a desired size and shape, and a 3D electrical element 10 having a size and shape suitable for a usage environment or the like may be obtained.

When producing a dispersion liquid, the ratio of isopropyl alcohol 30 is preferably such that the dispersion material (a combination of the nonlinear unit 11 and the conductor 12) is sufficiently suspended. When the dispersion material is excessive, the dispersion material remains on the surfaces of the dispersion liquid-containing body 33, and the possibility that the characteristics are affected cannot be ruled out, and furthermore, the surplus of the dispersion material may lead to be cost-disadvantageous. Examples of the dispersion solvent include pure water, ethanol, and dichloroethane, but not limited thereto, if dispersion materials can be dispersed in the dispersion solvent.

Further, for the ratio of the nonlinear unit 11 and the conductor 12, it is desirable that it is not insulated or linear short circuit. If the proportion of the conductor 12 is undersized, a problem such as electrical insulation may occur without generating a circuit, and if the proportion of the conductor 12 is excessive, problems such as short circuiting may occur.

The water-soluble porous structure 32 was removed by the hydrothermal 36, but depending on the specifications of the three-dimensional electric element 10 and the usage environment, the water-soluble porous structure 32 may not need to be removed. A three-dimensional electric element having a water-soluble porous structure 32 such as a sugar cube remains, or a 3D electrical element having an insoluble porous structure such as a urethane sponge or ZnO may also exist as one form. Since a three-dimensional electric element having a water-soluble porous structure or an insoluble porous structure has a certain degree of hardness, it can be expected to improve the placement accuracy of the input electrode and the output electrode.

In the above embodiment, a 3D electrical element 10 was produced using one water-soluble porous structure 32, but for example, a three-dimensional electric element may be created by combining a plurality of water-soluble porous structures having the same or different shapes. In this case, a three-dimensional electric element 10 having a desired shape and a desired size can be produced, and a three-dimensional electric element considering the usage environment and the like can be manufactured.

When the 3D electrical element 10 has a shape having a corner portion, in order to prevent chipping of the corner portion, it is preferable to perform chamfering processing or to process the cross section of the corner into an arc shape.

Specific shapes of the three-dimensional electric element 10 include cubes, cuboids, columnar bodies, cones, spherical bodies, annular bodies, cavity bodies, and the like. In connection to the 3D electrical element 10 of the input electrode 13 and the output electrode 14, it is preferable that the shape of the 3D electrical element 10 be a cube, a cuboid, or a columnar body, and the arrangement accuracy of the input electrode 13 and the output electrode 14 can be improved.

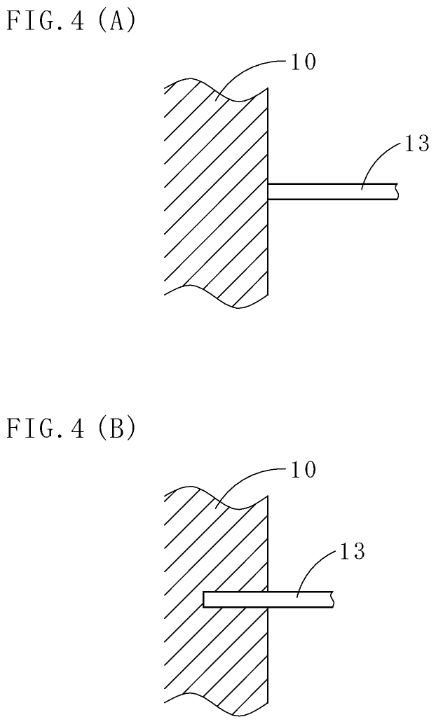

When the input electrode 13 and the output electrode 14 are connected to the 3D electrical element 10, the tip of each electrode is arranged so as to be in contact with the surface of the 3D electrical element 10 as shown in FIG. 4(A) (hereinafter referred to as “first arrangement”), and the tip of each electrode, as shown in FIG. 4(B), it can be arranged so as to pierce into the 3D electrical element 10 (hereinafter referred to as “second arrangement”). The arrangement of the electrodes is determined according to the specifications of the three-dimensional electric element and the like.

As an example of the arrangement of the electrode, the input electrode and the output power may be only one of the first arrangement and the second arrangement, or one of the input electrodes and output power may be set to a second arrangement and the other can be a first arrangement. Further, when a plurality of output electrodes are used as in the present embodiment, a part of the output electrodes may be set to the first arrangement and the remaining output power may be set to a second arrangement.

In the present embodiment, after generating a dispersion liquid-containing body 33 in which the nonlinear unit 11 and the conductor 12 are three-dimensionally arranged in the water-soluble porous structure 32, the dispersion liquid-containing body 33 is immersed with polydimethylsiloxane 34 which is a curable resin, and after curing, a process was performed to remove the water-soluble porous structure 32, but the manufacturing method for the three-dimensional electric element is not limited thereto.

Hereinafter, an example of a manufacturing method for a three-dimensional electric element different from the present embodiment will be described.

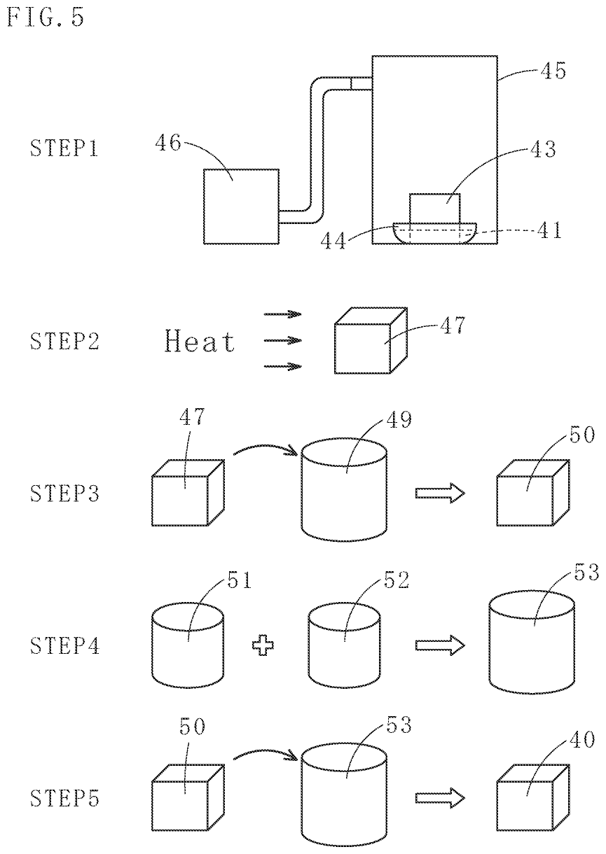

In the manufacturing method of the 3D electrical element 40 shown in FIG. 5, first, a tray 44 in which a liquid epoxy resin (for example, RSF 816) 41 and a water-soluble porous structure 43 are placed is accommodated in the chamber 45, and a vacuum pump 46 connected to the chamber 45 is operated. The water-soluble porous structure 43 is partially immersed in the epoxy resin 41, and the epoxy resin 41 is immersed in the water-soluble porous structure 43 by the decompression in the chamber 45 due to the operation of the vacuum pump 46 (so far, Step 1).

After the epoxy resin 41 is immersed in the entire water-soluble porous structure 43, the decompression state in the chamber 45 is released, and the water-soluble porous structure 43 in which the epoxy resin 41 has been impregnated (hereinafter the water-soluble porous structure 43 in this state is referred to as the resin-containing body 47) is taken out of the chamber 45, and as shown in FIG. 5, the epoxy resin 41 of the resin contained body 47 is cured by heat treatment (Step 2).

Next, the resin-containing body 47 is immersed in a solvent 49 such as hot water to dissolve the water-soluble porous structure 43 of the resin-containing body 47 to obtain a resin template 50 composed only of the cured epoxy resin 41 (Step 3). If the water-soluble porous structure 43 is a sugar cube, the water-soluble porous structure 43 is dissolved while keeping the temperature of the solvent 49 at about 50-70° C.

Thereafter, a solution 51 in which a polyacid (PMO₁₂), which is an example of a nonlinear unit, is dissolved in water or acetonitrile, and a solution 52 in which carbon nanotubes which are an example of a conductive part are dispersed in isopropanol are mixed, and the mixture is sonicated for about 4 hours to obtain a dispersion liquid 53 in which the polyacid and carbon nanotubes are dispersed (Step 4). Then, the resin template 50 is immersed in the dispersion liquid 53 to immerse the dispersion liquid 52 in the resin template 50, and sonication is performed for about 5 minutes to obtain a 3D electrical element 40 in which the polyacid and carbon nanotubes are supported (fixed) to the cured product 42 and arranged in a three-dimensional shape (Step 5).

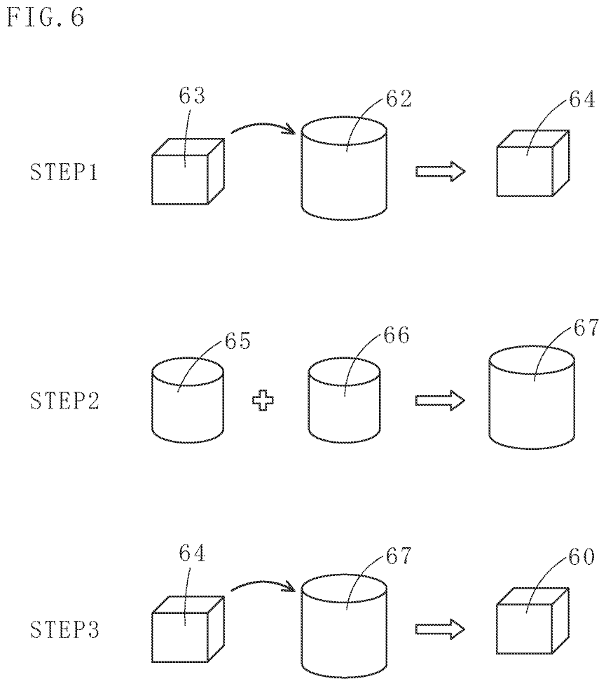

In the manufacturing method of the three-dimensional electric element 60 shown in FIG. 6, the melamine sponge 63 formed by the melamine resin is immersed in the cellulose-containing liquid 62 containing the cellulose fiber, and the melamine sponge 63 immersed in the cellulose-containing liquid 62 After sonication for about 1 minute, the process is dried, A resin template (an example of a porous structure) 64 containing cellulose fiber and cellulose is generated (Step 1).

Here, the cellulose-containing liquid 62 may be adjusted using a solution having a different concentration of cellulose fiber (for example, 0.01% by mass, 0.1% by mass, 1% by mass). From the viewpoint of enhancing the learning performance of the 3D electrical element 60, it is preferable that the concentration of the cellulose fiber of the cellulose-containing liquid 62 is adjusted to about 1% by mass. The drying treatment may be a drying process at about 50° C. using an oven or the like, but natural drying is preferable because voids are distributed throughout the structure.

Then, as shown in FIG. 6, a solution 65 in which a polyacid (PMO₁₂), which is an example of a nonlinear unit, is dissolved in water or acetonitrile, and a solution 66 in which carbon nanotubes, which are an example of a conductor, are dispersed in isopropanol by sonication for about 1 hour, and sonication for about 12 hours is performed to obtain a dispersion liquid 67 in which the polyacid and carbon nanotubes are dispersed (Step 2).

Thereafter, the resin template 64 is immersed in the dispersion liquid 67 and sonicated for about 2 minutes, the dispersion liquid 67 is immersed in the resin template 64, and the drying process is performed at about 50° C. by an oven. In addition, a protective film such as epoxy resin may be provided on the surface of the 3D electrical element 60 to increase the strength.

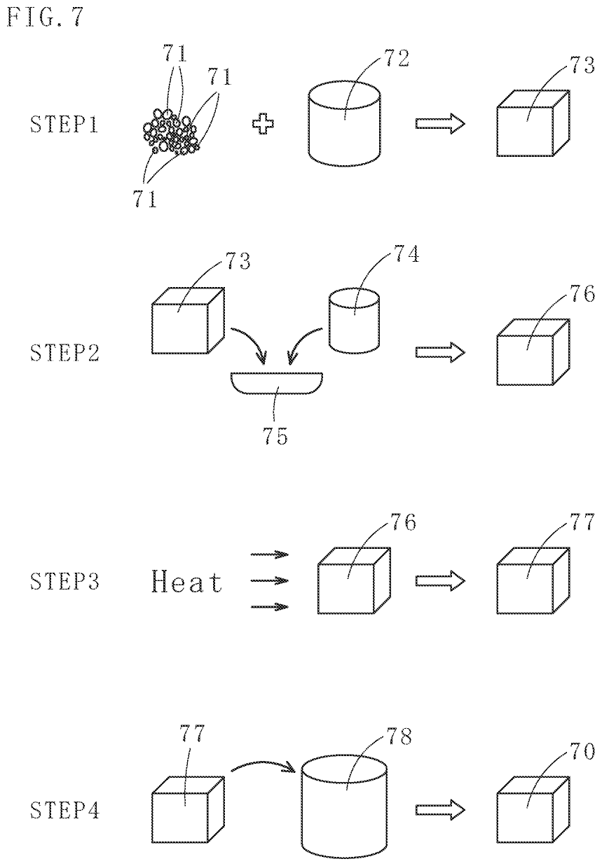

In addition, in the manufacturing method of the three-dimensional electric element 70 shown in FIG. 7, a water-soluble granular substance such as sugar grains (which may be a water-soluble powder) 71 and a polyacid that is an example of a nonlinear unit in the solvent and a dispersion liquid 72 in which carbon nanotubes are dispersed are dispersed Pressurization or the like is performed, A porous template 73 in which the dispersion liquid 72 is impregnated into the aggregate (structure) of water-soluble granular material 71 is formed (Step 1).

Next, as shown in FIG. 7, the porous template 73 is placed in a tray 75 together with the liquid thermosetting resin 74 to obtain a resin impregnating 76 in which the liquid thermosetting resin 74 is impregnated into the porous template 73 (Step 2). Impregnation of the thermosetting resin 74 into the porous template 73 can be performed using a vacuum pump.

Thereafter, the thermosetting resin 74 (thermosetting resin 74 impregnated in the porous template 73) of the resin impregnation 76 is cured by heating the resin impregnation 76 to obtain the solidification template 77 (Step 3).

Then, the water-soluble granular material 71 is dissolved and removed from the solidified template 77 by immersing the solidified template 77 in a solvent 78 such as hot water, and the polyacid and carbon nanotubes are supported (fixed) on a resinous porous body to obtain a 3D electrical element 70 arranged in a three-dimensional shape (Step 4). For the 3D electrical element 70, a protective film may be provided on the surface to increase the strength.

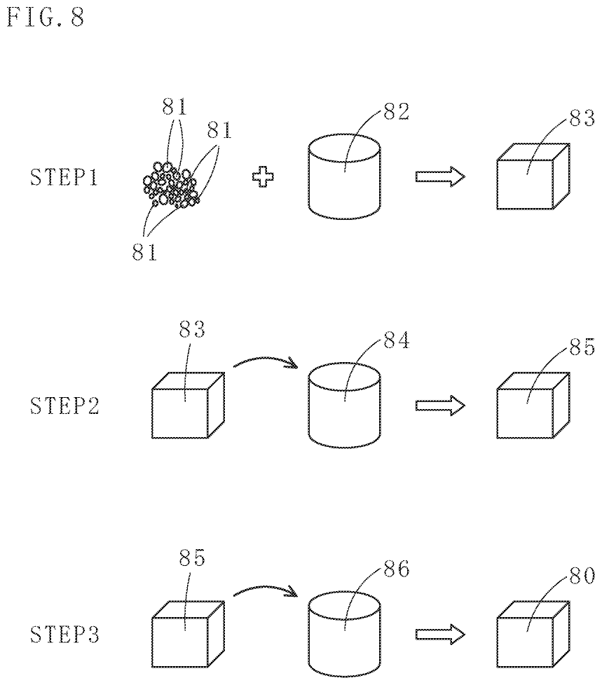

Further, as shown in FIG. 8, a water-soluble granular material 81 and a liquid curable resin 82 may be mixed to obtain a mixing template 83 (Step 1). For example, a mixture of water-soluble granular material 81 and liquid curable resin 82 can be used as a material and a 3D printer can be used to create a mixing template 83. By using a 3D printer, it is possible to form a mixed template 83 of various shapes. The mixing template 83 has a certain degree of hardness by curing the curable resin 82 by heat treatment or the like.

As shown in FIG. 8, by immersing the mixed template 83 in a solvent 84 such as hot water and removing the granular material 81 from the mixed template 83, a porous body 85 mainly composed of resin is obtained (Step 2), and by immersing the porous body 85 in the dispersion liquid 86 and performing a drying treatment, a 3D electrical element 80 in which a nonlinear unit and a conductor are arranged three-dimensionally is generated (Step 3).

Here, instead of immersing the porous body 85 in the dispersion liquid 86, the dispersion liquid 86 is sprayed on the porous body 85 with an injection machine, or the dispersion liquid 86 is dripped onto the porous body 85 so that the dispersion liquid 86 is immersed in the porous body 85. Even for the 3D electrical element 80, the strength may be increased by forming a protective film on the surface.

### Experimental Example

Next, an experiment performed to confirm the action effect of the present invention will be described.

In the experiment, a 3D electrical element (experimental example) in which polyoxometalate particles (nonlinear units) connected by carbon nanotubes (conductors) are arranged in a three-dimensional shape, and a two-dimensional electrical element (comparative example) in which particles of polyoxomethalate connected by carbon nanotubes (conductors) are arranged in a planar shape (comparative example) were used.

The three-dimensional electric element is obtained by curing polydimethylsiloxane to maintain a state in which polyoxometalate particles are arranged in a three-dimensional manner, and one needle-shaped input electrode and three needle-shaped output electrodes are inserted into this three-dimensional electric element to create a neural network system (hereinafter referred to as “3D neural network system”).

The two-dimensional electrical element is one in which polyoxometalate particles and carbon nanotubes are dispersed on an insulating substrate, and one plate-like input electrode and one plate-like output electrode are contacted with the two-dimensional electrical element to create a neural network system (hereinafter referred to as “2D neural network system”).

First, in the 3D neural network system, a sinusoidal pulse signal is input from the input electrode to the 3D electrical element, and the waveform of the signal output from the output electrode is a triangular wave, a saw wave, etc. Thereafter, a sinusoidal pulse signal is input from the input electrode to the three-dimensional electric element, a desired waveform is predicted by the three-dimensional electric element, and the waveform of the predicted signal from the output electrode is output, and this output signal is detected. Similar experiments were also performed on a 2D neural network system.

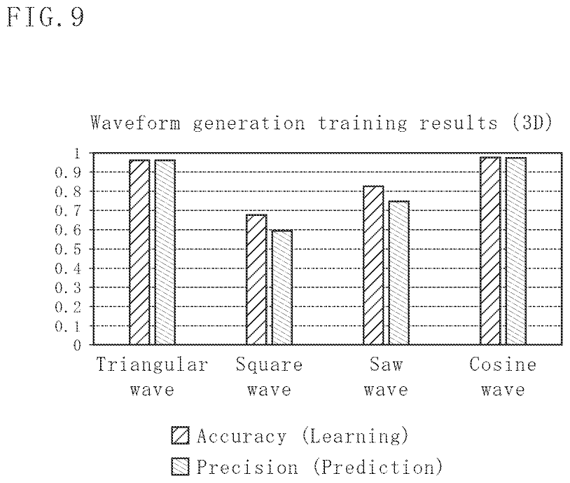

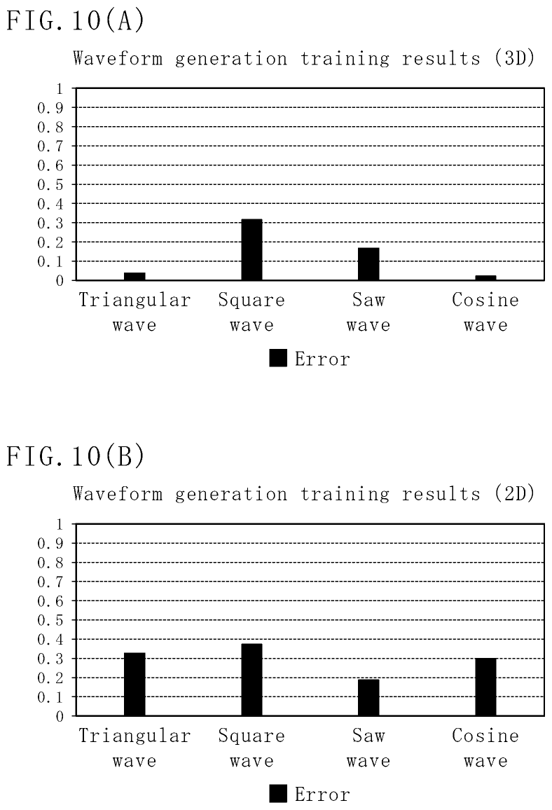

The experimental results of each desired waveform being a triangular wave, a square wave, a saw wave, and a cosine wave are shown in FIGS. 9, 10(A) and 10(B).

The accuracy (learning) and precision (prediction) in the experimental results of FIG. 9 are respectively quantified to what extent the waveform of the signal output from the output electrode matched the desired waveform set at the time of learning and prediction in the 3D electrical element, and the larger the number, the more it was matched.

In the experimental results of FIGS. 10(A) and 10(B), the error is a numerical value of how different the waveform of the signal output from the output electrode was with respect to the desired waveform set, and the higher the number, the greater the error.

From the experimental results in FIG. 9, it was confirmed that the accuracy value of the 3D neural network system was approximately 0.6 points or more at both the time of learning and prediction. Further, from the experimental results of FIGS. 10(A) and (B), it was confirmed that the error of the 3D neural network system was smaller than the error of the 2D neural network system.

As described above, examples of the present invention have been described, but the present invention is not limited to the above-described forms, and changes in conditions that do not deviate from the gist are all within the scope of application of the present invention.

For example, the nonlinear unit does not need to be particulated, and a nonlinear unit such as a needle-shaped, film-shaped, or void indicating tunnel coupling can be employed. The shape of the conductor is not particularly limited, and may be, for example, a particulate or film shape.

Then, a 3D electrical element may be configured by a conductive polymer provided with a junction (connecting portion) exhibiting nonlinear electrical voltage characteristics. In this case, in the conductive polymer, the junction corresponds to a nonlinear unit, and the portion excluding the junction corresponds to the conductor.

Furthermore, the shape of the input electrode and the output electrode is not limited, and may be, for example, a plate shape.

### INDUSTRIAL APPLICABILITY

According to the three-dimensional electric element according to the present invention, a machine learning system having the same, and manufacturing methods thereof, since the machine learning system can be made compact, it is possible to promote the mounting of a function learning system on a small device such as a mobile terminal or a wearable terminal.

### REFERENCE SIGHS LIST

10, 10′: 3D electrical element, 11: Nonlinear unit, 12: Conductor, 13, 13′: Input electrode, 14, 14′: Output electrode, 15′: Widening portion, 20, 20′: Neural network system, 30: Isopropyl alcohol, 31: Dispersion liquid, 32: Water-soluble porous structure, 33: Dispersion liquid-containing body, 34: Polydimethylsiloxane, 35: Cured product, 36: Hydrothermal water, 40: 3D electrical element, 41: Epoxy resin, 42: Cured product, 43: Water-soluble porous structure, 44: Tray, 45: Chamber, 46: Vacuum pump, 47: Resin containing body, 49: Solvent, 50: Resin template, 51, 52: Solution, 53: Dispersion liquid, 60: 3D electrical element, 61: Cured product, 62: Cellulose-containing liquid, 63: Melamine sponge, 64: Resin template, 65, 66: Solution, 67: Dispersion liquid, 70: 3D electrical element, 71: Granular material, 72: Dispersion liquid, 73: Porous template, 74: Thermosetting resin, 75: Tray, 76: Receiving impregnation, 77: Solidification template, 78: Solvent, 80: 3D electrical element, 81: Granular material, 82: Curable resin, 83: Mixed template, 84: Solvent, 85: Porous body, 86: Dispersion liquid

1-6. (canceled)

7. A three-dimensional electric element, comprising:
four or more nonlinear units each having nonlinear current-voltage characteristics; and
an electric conductor connecting the nonlinear units, the nonlinear units being arranged in a three-dimensional manner.

8. The three-dimensional electric element according to claim 7, wherein
the three-dimensional electric element has a sponge shape.

9. A machine learning system, comprising:
a three-dimensional electric element, the three-dimensional electric element including four or more nonlinear units each having nonlinear current-voltage characteristics and an electric conductor connecting the nonlinear units, the nonlinear units being arranged in a three-dimensional manner; and
an input electrode and an output electrode, each of the input electrode and the output electrode being connected to the three-dimensional electric element.

10. The machine learning system according to claim 9, wherein
the three-dimensional electric element has a sponge shape.

11. The machine learning system according to claim 9, wherein
the three-dimensional electric element includes three or more sides, and the output electrode is inserted into or in contact with each side of at least three of the sides.

12. A method for manufacturing a three-dimensional electric element, comprising:
a step of causing a dispersion to be immersed in a porous structure to obtain a dispersion-containing body, the dispersion in which four or more nonlinear units each having nonlinear current-voltage characteristics and an electric conductor connecting the nonlinear units are put; and
a step of causing the dispersion-containing body to be cured with a curable resin to obtain a three-dimensional electric element, the three-dimensional electric element including the nonlinear units arranged in a three-dimensional manner.

13. A method for manufacturing a machine learning system, comprising:
a step of causing a dispersion to be immersed in a porous structure to obtain a dispersion-containing body, the dispersion in which four or more nonlinear units each having nonlinear current-voltage characteristics and an electric conductor connecting the nonlinear units are put;
a step of causing the dispersion-containing body to be cured with a curable resin to obtain a three-dimensional electric element, the three-dimensional electric element including the nonlinear units arranged in a three-dimensional manner; and
a step of connecting an input electrode and an output electrode to the three-dimensional electric element.
